(19) United States
(12) Patent Application Publication
(10) Pub. No.: US 2023/0395624 A1
(43) Pub. Date: Dec. 7, 2023

(54) SENSOR PACKAGE STRUCTURE AND CHIP-SCALE SENSOR PACKAGE STRUCTURE

(71) Applicant: TONG HSING ELECTRONIC INDUSTRIES, LTD., Taipei City (TW)

(72) Inventors: CHIA-SHUAI CHANG, Hsin-Chu County (TW); CHIEN-CHEN LEE, Hsin-Chu County (TW); LI-CHUN HUNG, Hsin-Chu County (TW)

(21) Appl. No.: 18/165,285

(22) Filed: Feb. 6, 2023

Related U.S. Application Data
(60) Provisional application No. 63/349,565, filed on Jun. 6, 2022.

(30) Foreign Application Priority Data
Nov. 28, 2022 (TW) 111145343

(51) Int. Cl. H01L 27/146

(52) U.S. Cl. CPC H01L 27/14618; H01L 27/14623; H01L 27/14636

(57) ABSTRACT

A sensor package structure and a chip-scale sensor package structure are provided. The chip-scale sensor package structure includes a sensor chip, a supporting layer having a ring-shape, and a light-permeable layer. A top surface of the sensor chip includes a sensing region and a carrying region that surrounds the sensing region. The supporting layer is disposed on the carrying region, and the light-permeable layer is disposed on the supporting layer through a ring-shaped segment thereof, so that the light-permeable layer, the supporting layer, and the sensor chip jointly define an enclosed space. The ring-shaped segment has a ring-shaped roughened region. A projection space defined by orthogonally projecting the ring-shaped roughened region toward the top surface of the sensor chip is located outside of the sensing region and overlaps an entirety of the supporting layer and a part of the enclosed space.

### CROSS-REFERENCE TO RELATED PATENT APPLICATION

This application claims the benefit of priority to Taiwan Patent Application No. 111145343, filed on Nov. 28, 2022. The entire content of the above identified application is incorporated herein by reference.

This application claims the benefit of priority to the U.S. Provisional Patent Application Ser. No. 63/349,565 filed on Jun. 6, 2022, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure and a chip-scale sensor package structure.

### BACKGROUND OF THE DISCLOSURE

A conventional sensor package structure includes a glass board, a sensor chip, and an adhesive layer that adheres the glass board and the sensor chip. Since the sensing result of the sensor chip is easily affected through the structural change of the chip, improvements to the conventional sensor package structure have always been focused on the adhesive layer for increasing the connection effect between the adhesive layer and other components. However, this direction of improvement is not without its limitations.

### SUMMARY OF THE DISCLOSURE

In response to the above-referenced technical inadequacy, the present disclosure provides a sensor package structure and a chip-scale sensor package structure to effectively improve on the issues associated with conventional sensor package structures.

In order to solve the above-mentioned problems, one of the technical aspects adopted by the present disclosure is to provide a sensor package structure, which includes a substrate, a sensor chip, a supporting layer, a light-permeable layer, and an encapsulant. The sensor chip is disposed on and electrically coupled to the substrate, and a top surface of the sensor chip includes a sensing region and a carrying region that surrounds the sensing region. The supporting layer has a ring shape and is disposed on the carrying region of the sensor chip. The light-permeable layer has an outer surface and an inner surface that is opposite to the outer surface. The light-permeable layer has a transparent segment and a ring-shaped segment that surrounds the transparent segment. The ring-shaped segment is disposed on the supporting layer, so that the light-permeable layer, the supporting layer, and the sensor chip jointly define an enclosed space. The encapsulant is formed on the substrate. The sensor chip, the supporting layer, and the light-permeable layer are embedded in the encapsulant, and at least part of the outer surface of the light-permeable layer is exposed from the encapsulant. The ring-shaped segment has a ring-shaped roughened region, and a projection space defined by orthogonally projecting the ring-shaped roughened region toward the top surface of the sensor chip is located outside of the sensing region and overlaps an entirety of the supporting layer and a part of the enclosed space.

In order to solve the above-mentioned problems, another one of the technical aspects adopted by the present disclosure is to provide a chip-scale sensor package structure, which includes a sensor chip, a supporting layer, and a light-permeable layer. A top surface of the sensor chip includes a sensing region and a carrying region that surrounds the sensing region. The supporting layer has a ring shape and is disposed on the carrying region of the sensor chip. The light-permeable layer has an outer surface and an inner surface that is opposite to the outer surface. The light-permeable layer has a transparent segment and a ring-shaped segment that surrounds the transparent segment. The ring-shaped segment is disposed on the supporting layer, so that the light-permeable layer, the supporting layer, and the sensor chip jointly define an enclosed space. The ring-shaped segment has a ring-shaped roughened region, and a projection space defined by orthogonally projecting the ring-shaped roughened region toward the top surface of the sensor chip is located outside of the sensing region and overlaps an entirety of the supporting layer and a part of the enclosed space.

Therefore, any one of the sensor package structure and the chip-scale sensor package structure in the present disclosure is provided with the ring-shaped roughened region formed on the ring-shaped segment of the light-permeable layer, so that the bonding force between the light-permeable layer and the supporting layer can be increased for effectively preventing the light-permeable layer from peeling off the supporting layer or preventing the light-permeable layer and the supporting layer from having a delamination therebetween.

Moreover, since any one of the sensor package structure and the chip-scale sensor package structure in the present disclosure is provided with the ring-shaped roughened region formed on the ring-shaped segment of the light-permeable layer, light traveling on the ring-shaped roughened region by passing through the light-permeable layer can be scattered to prevent the light from being reflected to the sensing region through the supporting layer, thereby effectively reducing the flare phenomenon of any one of the sensor package structure and the chip-scale sensor package structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a top view of FIG. 1 when an encapsulant is omitted;

FIG. 3 is a cross-sectional view taken along line III-III of FIG. 1;

FIG. 4A is an enlarged view of part IV of FIG. 3;

FIG. 4B is an enlarged view showing the part IV of FIG. 3 in another configuration;

FIG. 5 is a cross-sectional view showing the sensor package structure of FIG. 1 in another configuration;

FIG. 6 is an enlarged view of part VI of FIG. 5;

FIG. 7 is a cross-sectional view of the sensor package structure according to a second embodiment of the present disclosure;

FIG. 8 is a cross-sectional view of the sensor package structure in another configuration according to the second embodiment of the present disclosure;

FIG. 9 is a cross-sectional view of the sensor package structure according to a third embodiment of the present disclosure;

FIG. 10 is a cross-sectional view of the chip-scale sensor package structure according to a fourth embodiment of the present disclosure;

FIG. 11 is a perspective view of the chip-scale sensor package structure according to a fifth embodiment of the present disclosure;

FIG. 12 is a top view of FIG. 11;

FIG. 13 is a cross-sectional view taken along line XIII-XIII of FIG. 11;

FIG. 14 is a cross-sectional view showing the chip-scale sensor package structure of FIG. 11 in another configuration;

FIG. 15 is a cross-sectional view of the chip-scale sensor package structure according to a sixth embodiment of the present disclosure;

FIG. 16 is a cross-sectional view of the chip-scale sensor package structure according to a seventh embodiment of the present disclosure; and

FIG. 17 is a cross-sectional view of the chip-scale sensor package structure in another configuration according to the seventh embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

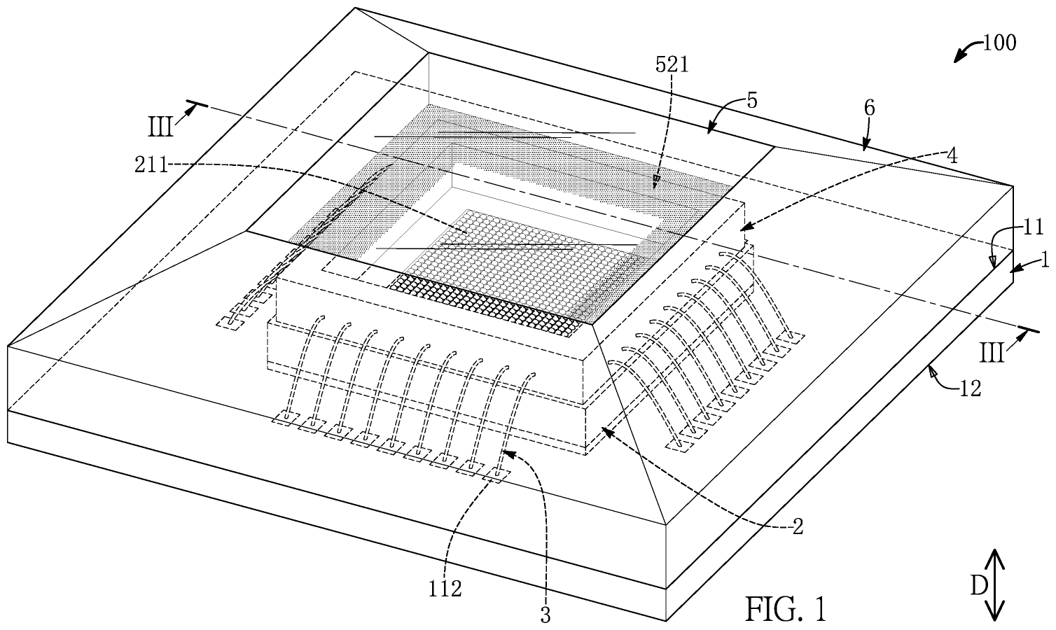

Referring to FIG. 1 to FIG. 6, a first embodiment of the present disclosure provides a sensor package structure 100. In other words, any package structure not encapsulating a sensor chip therein has a structural design different from that of the sensor package structure 100 of the present embodiment.

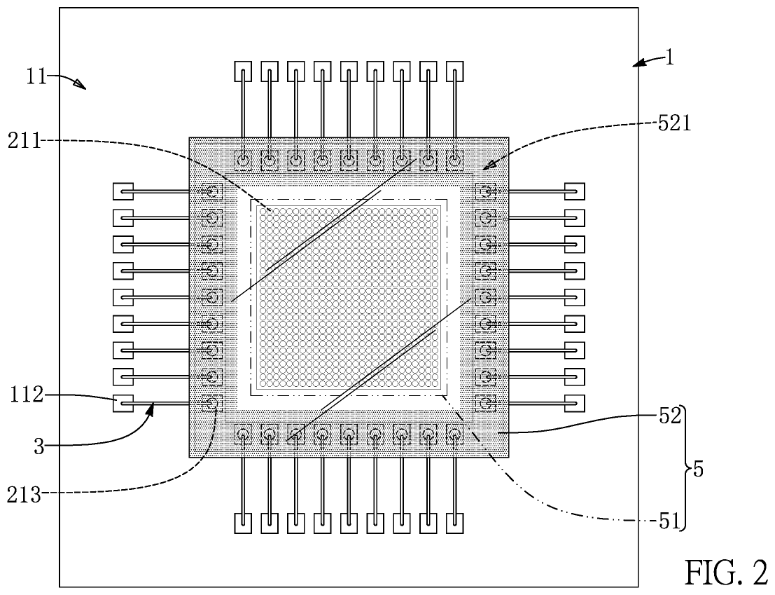

As shown in FIG. 2 to FIG. 4A, the sensor package structure 100 includes a substrate 1, a sensor chip 2 disposed on the substrate 1, a plurality of metal wires 3 electrically coupled to the sensor chip 2 and the substrate 1, a supporting layer 4 having a ring shape and disposed on the sensor chip 2, a light-permeable layer 5 disposed on the supporting layer 4, and an encapsulant 6 that is formed on the substrate 1.

The sensor package structure 100 in the present embodiment includes the above components, but can be adjusted or changed according to design requirements. For example, in other embodiments of the present disclosure not shown in the drawings, the sensor package structure 100 can be provided without the metal wires 3, and the sensor chip 2 is fixed onto and electrically coupled to the substrate 1 in an adhering manner. The structure and connection relationship of each component of the sensor package structure 100 will be recited in the following description.

The substrate 1 of the present embodiment has a square shape or a rectangular shape, but the present disclosure is not limited thereto. An upper surface 11 of the substrate 1 includes a chip-bonding region 111 arranged approximately on a center portion thereof, and the substrate 1 includes a plurality of bonding pads 112 that are disposed on the upper surface 11 and are arranged outside of the chip-bonding region 111. The bonding pads 112 in the present embodiment are in a ring-shaped arrangement, but the present disclosure is not limited thereto. For example, in other embodiments of the present disclosure not shown in the drawings, the bonding pads 112 can be arranged in two rows respectively at two opposite sides of the chip-bonding region 111.

In addition, the substrate 1 can be further provided with a plurality of soldering balls 7 disposed on a lower surface 12 thereof. The substrate 1 can be soldered onto an electronic component (not shown in the drawings) through the soldering balls 7, thereby electrically connecting the sensor package structure 100 to the electronic component.

The sensor chip 2 in the present embodiment has a square shape or a rectangular shape, and is an image sensor chip, but the present disclosure is not limited thereto. A bottom surface 22 of the sensor chip 2 is fixed onto the chip-bonding region 111 of the substrate 1 (through a chip-bonding adhesive along a predetermined direction D). In other words, the sensor chip 2 is arranged to be surrounded on the inside of the bonding pads 112. Moreover, a top surface 21 of the sensor chip 2 has a sensing region 211 and a carrying region 212 that has a ring shape arranged around the sensing region 211. Two ends of each of the metal wires 3 are respectively connected to the substrate 1 and the carrying region 212 of the sensor chip 2, so that the substrate 1 and the sensor chip 2 are electrically coupled to each other.

Specifically, the sensor chip 2 includes a plurality of connection pads 213 arranged on the carrying region 212. In other words, the connection pads 213 are arranged outside of the sensing region 211. The number and positions of the connection pads 213 of the sensor chip 2 in the present embodiment correspond to those of the bonding pads 112 of the substrate 1. In other words, the connection pads 213 in the present embodiment are substantially in a ring-shaped arrangement. Moreover, the two ends of each of the metal wires 3 are respectively connected to one of the bonding pads 112 and the corresponding connection pad 213.

The supporting layer 4 is disposed on the carrying region 212 of the sensor chip 2 and surrounds the sensing region 211. Moreover, the supporting layer 4 in the present embodiment is limited to be an ultraviolet (UV) curing layer (or a curing layer). In other words, the supporting layer 4 of the present embodiment is a structure that can be cured by being irradiated with a UV light, but the present disclosure is not limited thereto.

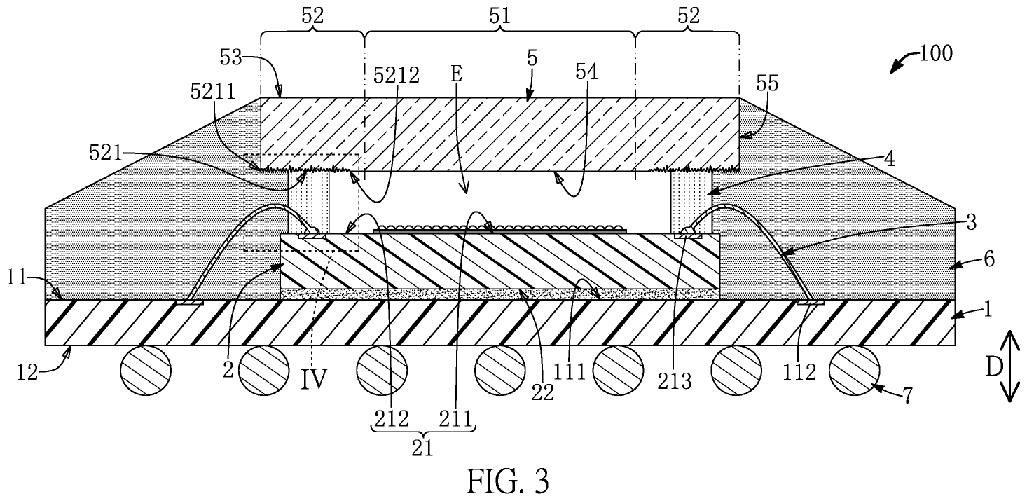

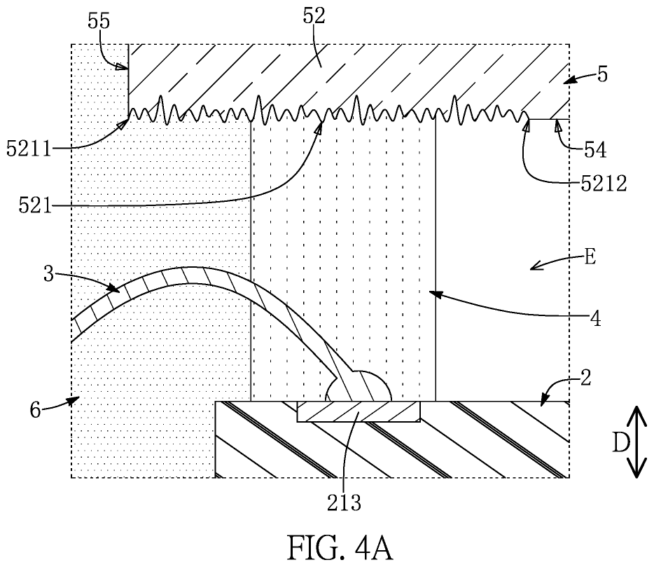

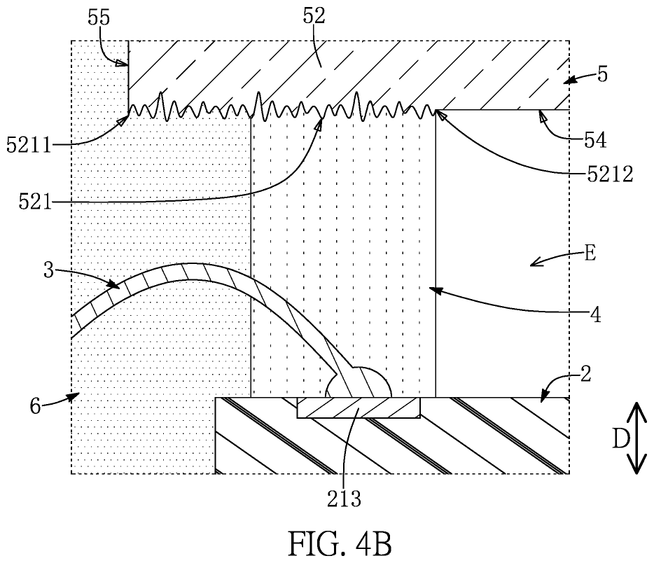

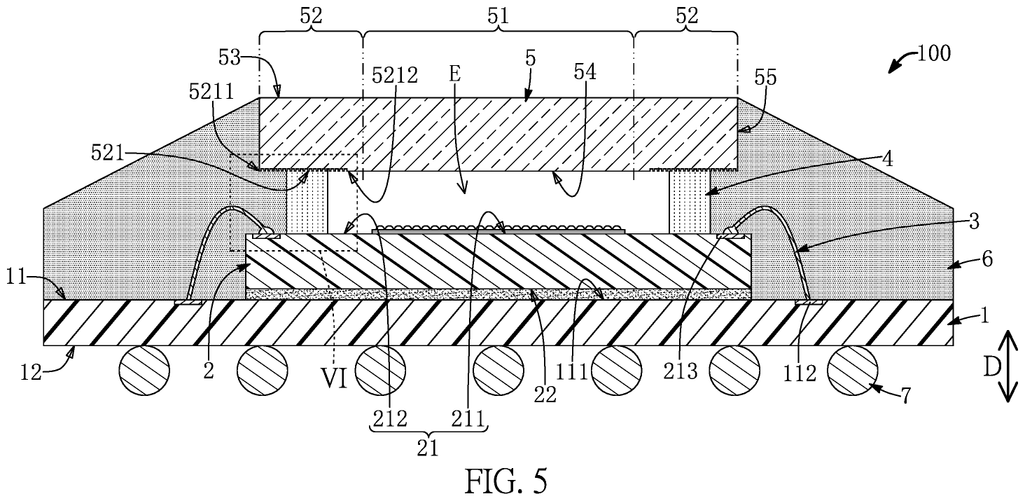

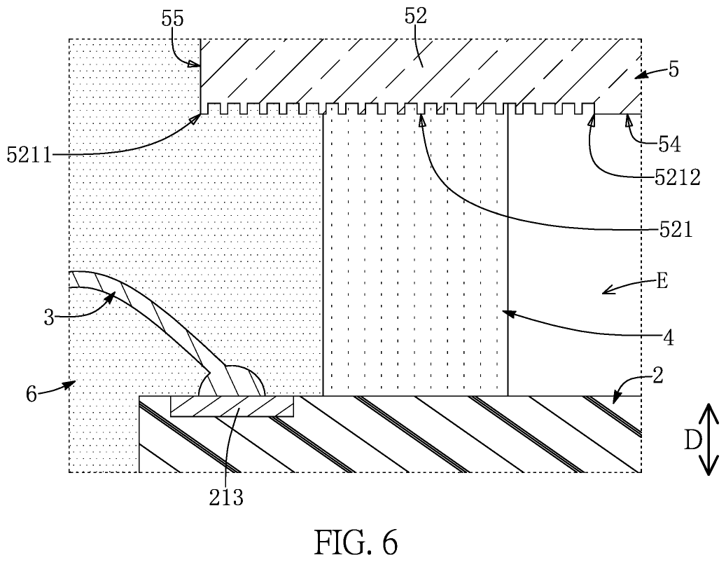

Specifically, as shown in FIG. 3 and FIG. 4A, a part of each of the metal wires 3 is embedded in the supporting layer 4, and a remaining part of each of the metal wires 3 is embedded in the encapsulant 6, but the present disclosure is not limited thereto. For example, as shown in FIG. 5 and FIG. 6, the supporting layer 4 can be arranged inside of the metal wires 3 and is not in contact with any one of the metal wires 3 (i.e., each of the metal wires 3 is arranged outside of the supporting layer 4 and is embedded in the encapsulant 6).

As shown in FIG. 2 to FIG. 4A, the light-permeable layer 5 in the present embodiment is a transparent and flat glass board, but the present disclosure is not limited thereto. The light-permeable layer 5 has a transparent segment 51 and a ring-shaped segment 52 that surrounds the transparent segment 51. The light-permeable layer 5 is disposed on the supporting layer 4 through the ring-shaped segment 52, so that the light-permeable layer 5, the supporting layer 4, and the sensor chip 2 jointly define an enclosed space E.

It should be noted that the shape and size of the transparent segment 51 in the present embodiment substantially correspond to those of the sensing region 211; in other words, a projection region defined by orthogonally projecting the transparent segment 51 onto the top surface 21 of the sensor chip 2 along the predetermined direction D is substantially overlapped with an entirety of the sensing region 211, but the present disclosure is not limited thereto. For example, in other embodiments of the present disclosure not shown in the drawings, the size of the transparent segment 51 can be slightly greater than that of the sensing region 211.

Moreover, the ring-shaped segment 52 has a ring-shaped roughened region 521, and a top side of the supporting layer 4 is substantially gaplessly connected to the ring-shaped roughened region 521. In other words, the top side of the supporting layer 4 and the ring-shaped roughened region 521 are concave-convex structures being complementary to each other. Furthermore, a projection space defined by orthogonally projecting the ring-shaped roughened region 521 toward the top surface 21 of the sensor chip 2 (along the predetermined direction D) is located outside of the sensing region 211 and overlaps an entirety of the supporting layer 4 and a part of the enclosed space E.

Accordingly, the sensor package structure 100 of the present embodiment is provided with the ring-shaped roughened region 521 formed on the ring-shaped segment 52 of the light-permeable layer 5, so that the bonding force between the light-permeable layer 5 and the supporting layer 4 can be increased for effectively preventing the light-permeable layer 5 from peeling off the supporting layer 4 or preventing the light-permeable layer 5 and the supporting layer 4 from having a delamination therebetween. It should be noted that the ring-shaped roughened region 521 formed on the light-permeable layer 5 has a lower production difficulty and a lower cost with respect to the ring-shaped roughened region 521 formed on other components (e.g., the sensor chip 2 or the supporting layer 4), so that any roughened region not formed on a light-permeable layer is different from the ring-shaped roughened region 521 provided by the present embodiment.

Moreover, since the sensor package structure 100 of the present embodiment is provided with the ring-shaped roughened region 521 formed on the ring-shaped segment 52 of the light-permeable layer 5, light arrived at the ring-shaped roughened region 521 by passing through the light-permeable layer 5 can be scattered to prevent the light from being reflected to the sensing region 211 through the supporting layer 4, thereby effectively reducing the flare phenomenon of the sensor package structure 100.

In addition, the light-permeable layer 5 of the present embodiment is configured to allow that light passing through the ring-shaped segment 52 to be scattered at the ring-shaped roughened region 521 toward the supporting layer 4. In order to enable the supporting layer 4 to be uniformly irradiated, the light-permeable layer 5 of the present embodiment preferably has at least part of the following features, but the present disclosure is not limited thereto.

The light-permeable layer 5 has an outer surface 53, an inner surface 54 that is opposite to the outer surface 53, and a surrounding lateral surface 55 that is connected to the outer surface 53 and the inner surface 54. The ring-shaped roughened region 521 is formed on the inner surface 54 of the light-permeable layer 5 (i.e., a part of the inner surface 54 on the ring-shaped segment 52), and an outer edge 5211 of the ring-shaped roughened region 521 is arranged outside of the supporting layer 4 and is preferably flush with the surrounding lateral surface 55. Accordingly, the ring-shaped roughened region 521 can be provided to increase an area of the light-permeable layer 5 in contact with the supporting layer 4 and the encapsulant 6, thereby increasing the bonding force between the light-permeable layer 5 and any one of the supporting layer 4 and the encapsulant 6.

In addition, an inner edge 5212 of the ring-shaped roughened region 521 can be located in the enclosed space E (or located inside of the supporting layer 4) as shown in FIG. 4A, but the inner edge 5212 is not in contact with the transparent segment 51; or, the inner edge 5212 of the ring-shaped roughened region 521 can be flush with an inner side of the supporting layer 4 (i.e., the inner edge 5212 is not located in the enclosed space E) as shown in FIG. 4B.

Moreover, the ring-shaped roughened region 521 in the present embodiment has a haze being within a range from 10% to 90%, and the haze is preferably within a range from 30% to 90%, but the present disclosure is not limited thereto. In addition, the ring-shaped roughened region 521 can have an irregular arrangement as shown in FIG. 4A or FIG. 4B according to design requirements; or, the ring-shaped roughened region 521 can be a patterned array as shown in FIG. 6.

In summary, when the supporting layer 4 of the sensor package structure 100 in the present embodiment is the light curing layer, the ring-shaped roughened region 521 enables a lot of light to be scattered onto the supporting layer 4 by having specific characteristics, so that the supporting layer 4 can be entirely solidified to prevent the light-permeable layer 5 from being tilted and to further prevent the supporting layer 4 and the light-permeable layer 5 from having the delamination therebetween. Accordingly, the yield of the sensor package structure 100 can be increased.

The encapsulant 6 of the present embodiment is opaque for blocking a visible light from passing therethrough. The encapsulant 6 is a liquid encapsulation and is formed on the upper surface 11 of the substrate 1, and edges of the encapsulant 6 are flush with edges of the substrate 1. The sensor chip 2, the supporting layer 4, the light-permeable layer 5, and at least part of each of the metal wires 3 are embedded in the encapsulant 6, and at least part of the outer surface 53 of the light-permeable layer 5 is exposed from the encapsulant 6, but the present disclosure is not limited thereto.

### Second Embodiment

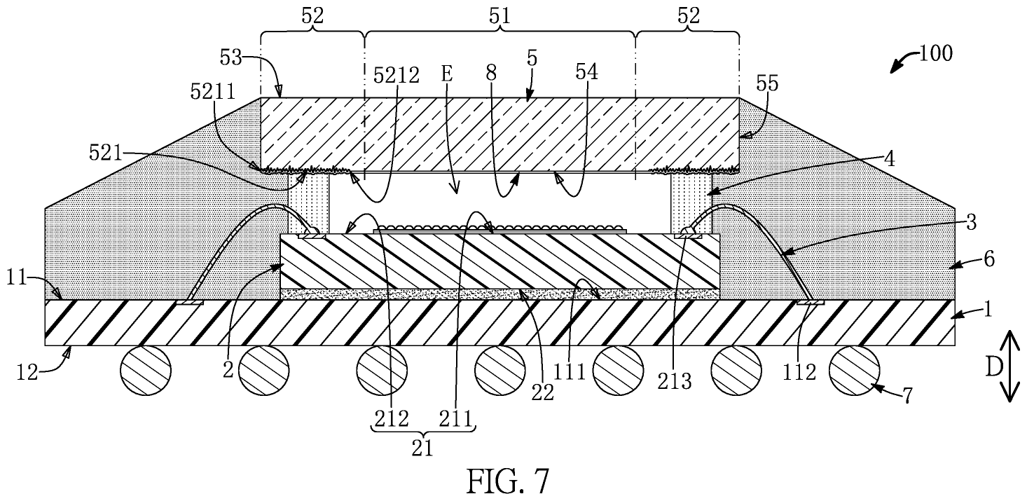

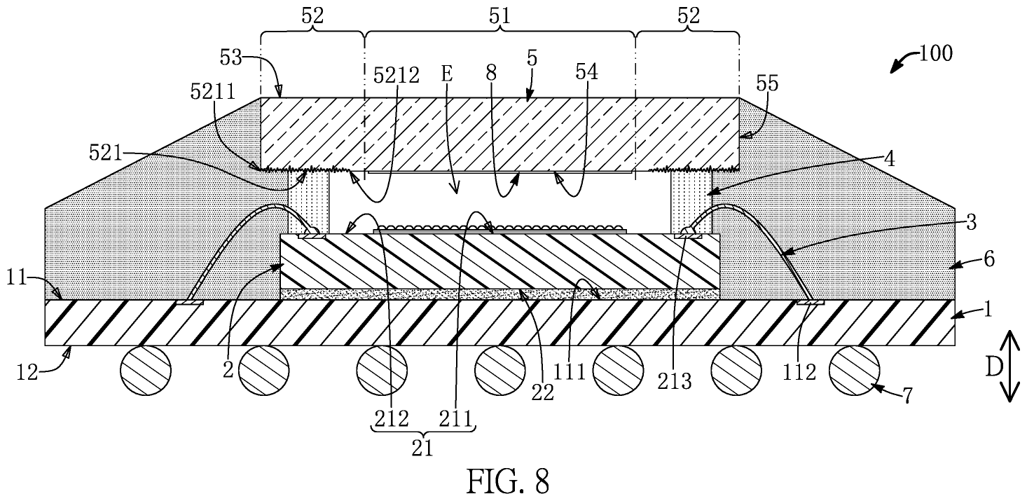

Referring to FIG. 7 and FIG. 8, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the sensor package structure 100 further includes an anti-reflection layer 8 formed on the inner surface 54 of the light-permeable layer 5. Specifically, the anti-reflection layer 8 can cover an entirety of the inner surface 54 as shown in FIG. 7; in other words, the anti-reflection layer 8 covers the ring-shaped roughened region 521. Or, the anti-reflection layer 8 can be arranged inside of the ring-shaped roughened region 521 as shown in FIG. 8; in other words, the anti-reflection layer 8 does not cover the ring-shaped roughened region 521.

### Third Embodiment

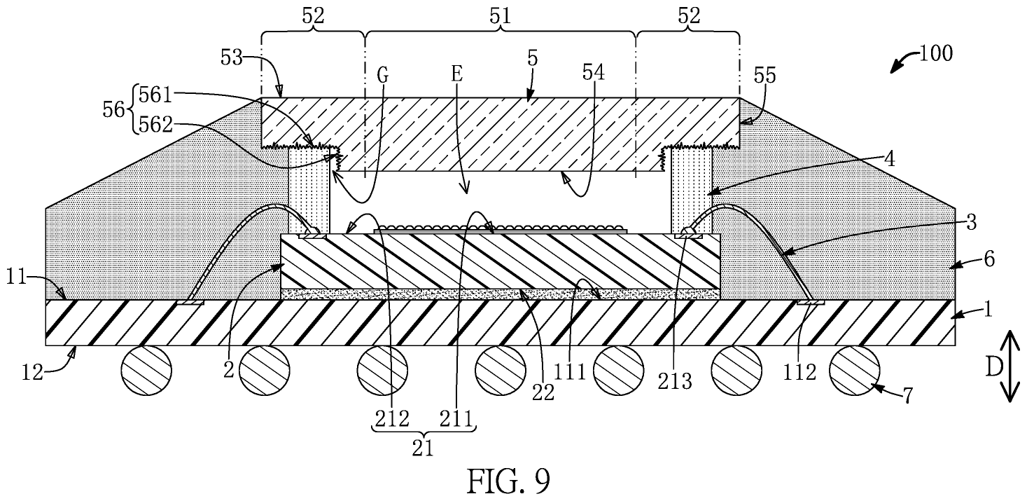

Referring to FIG. 9, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

In the present embodiment, the ring-shaped segment 52 has an inner ring-shaped groove 56 formed on the inner surface 54. The inner ring-shaped groove 56 has a tread surface 561 (connected to the surrounding lateral surface and a riser surface 562 that connects the tread surface 561 and the inner surface 54. The ring-shaped roughened region 521 is formed on the tread surface 561 and the riser surface 562. The ring-shaped roughened region 521 in the present embodiment is preferably formed on an entirety of the tread surface 561 and an entirety of the riser surface 562, but the present disclosure is not limited thereto.

Specifically, the supporting layer 4 is connected to the tread surface 561 (and a part of the ring-shaped roughened surface 521 arranged on the tread surface 561), and the supporting layer 4 and the riser surface 562 have an overflow gap G therebetween, thereby preventing the supporting layer 4 from extending (or flowing) to the transparent segment 51. In addition, the encapsulant 6 covers (and is connected to) a part of the tread surface (and another part of the ring-shaped roughened surface 521 arranged on the part of the tread surface 561), thereby increasing the bonding force between the encapsulant 6 and the light-permeable layer 5.

### Fourth Embodiment

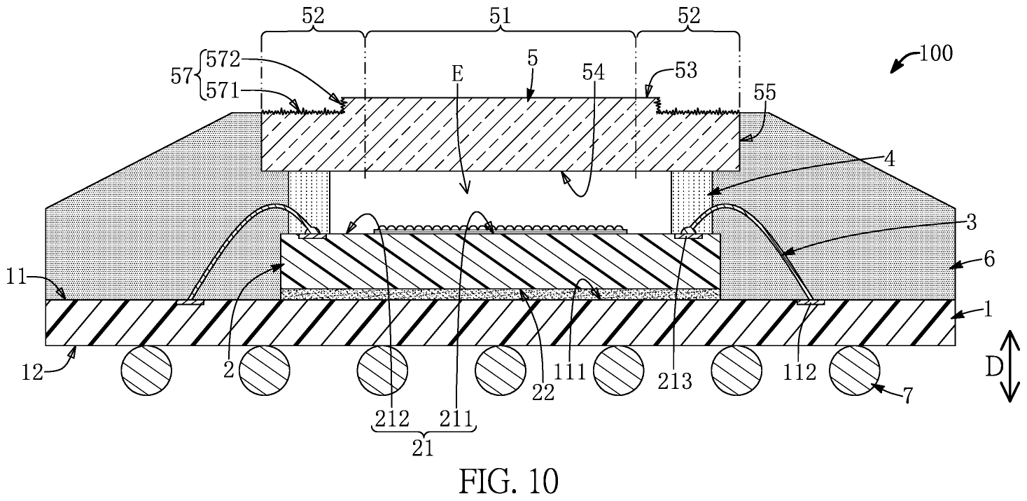

Referring to FIG. 10, a fourth embodiment of the present disclosure, which is similar to the first embodiment of the present disclosure, is provided. For the sake of brevity, descriptions of the same components in the first and fourth embodiments of the present disclosure will be omitted herein, and the following description only discloses different features between the first and fourth embodiments.

In the present embodiment, the ring-shaped segment 52 has an outer ring-shaped groove 57 formed on the outer surface 53. The outer ring-shaped groove 57 has a tread surface 571 (connected to the surrounding lateral surface and a riser surface 572 that connects the tread surface 571 and the outer surface 53. The ring-shaped roughened region 521 is formed on the tread surface 571 and the riser surface 572. The ring-shaped roughened region 521 in the present embodiment is preferably formed on an entirety of the tread surface 571 and an entirety of the riser surface 572, but the present disclosure is not limited thereto. In addition, a top side of the encapsulant 6 is flush with the tread surface 571 and is not in contact with the outer ring-shaped groove 57, thereby avoiding affecting the performance of the ring-shaped roughened region 521.

### Fifth Embodiment

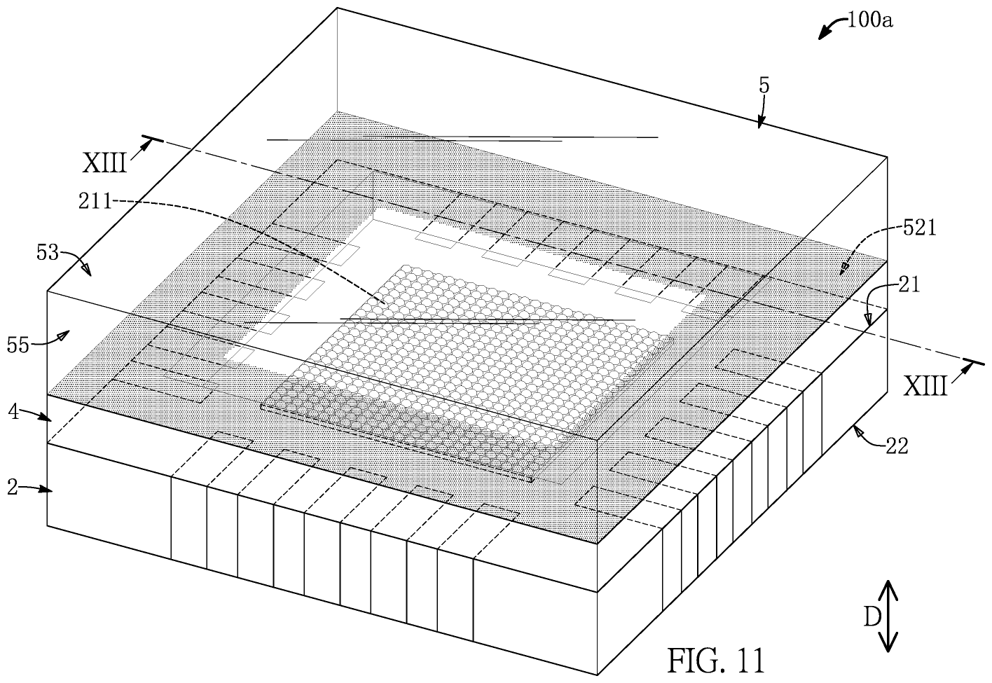

Referring to FIG. 11 to FIG. 14, a fifth embodiment of the present disclosure provides a chip-scale sensor package structure 100a. In other words, any package structure not being chip-scale has a structural design different from that of the chip-scale sensor package structure 100a of the present embodiment.

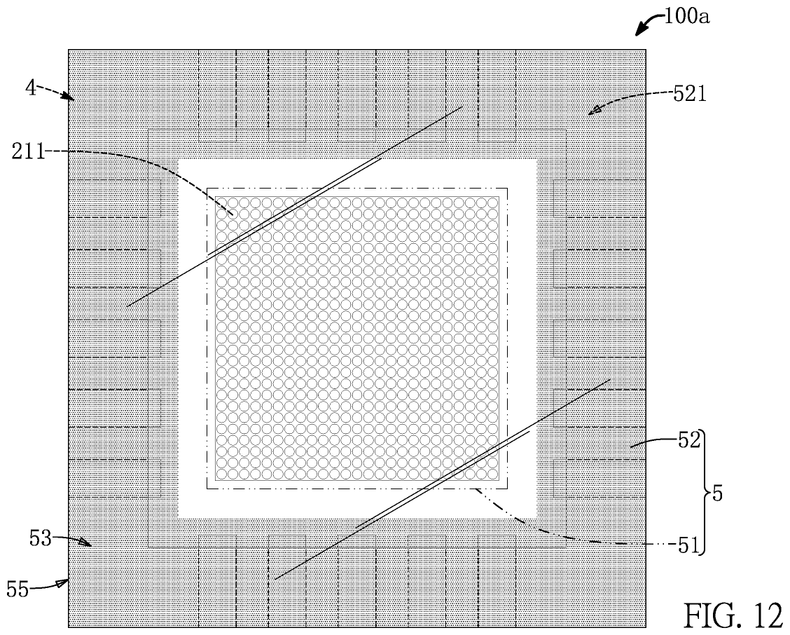

As shown in FIG. 12 to FIG. 14, the chip-scale sensor package structure 100a includes a sensor chip 2, a supporting layer 4 having a ring shape and being disposed on the sensor chip 2, and a light-permeable layer 5 that is disposed on the supporting layer 4. In other words, the chip-scale sensor package structure 100a does not have any encapsulant for achieving its chip-scale.

In the present embodiment, the sensor chip 2 has a square shape or a rectangular shape, and is an image sensor chip, but the present disclosure is not limited thereto. A top surface 21 of the sensor chip 2 has a sensing region 211 and a carrying region 212 that has a ring shape arranged around the sensing region 211. Moreover, the chip-scale sensor package structure 100a can be soldered and fixed onto an electronic component (not shown in the drawings) through a bottom surface 22 of the sensor chip 2, so that the chip-scale sensor package structure 100a is electrically coupled to the electronic component.

The supporting layer 4 is disposed on the carrying region 212 of the sensor chip 2 and surrounds the sensing region 211. Moreover, the supporting layer 4 in the present embodiment is limited to being a UV curing layer (or a curing layer). In other words, the supporting layer 4 of the present embodiment is a structure that can be cured by being irradiated with UV light, but the present disclosure is not limited thereto.

The light-permeable layer 5 in the present embodiment is a transparent and flat glass board, but the present disclosure is not limited thereto. The light-permeable layer 5 has a transparent segment 51 and a ring-shaped segment 52 that surrounds the transparent segment 51. The light-permeable layer 5 is disposed on the supporting layer 4 through the ring-shaped segment 52, so that the light-permeable layer 5, the supporting layer 4, and the sensor chip 2 jointly define an enclosed space E.

It should be noted that the shape and size of the transparent segment 51 in the present embodiment substantially correspond to those of the sensing region 211; in other words, a projection region defined by orthogonally projecting the transparent segment 51 onto the top surface 21 of the sensor chip 2 along the predetermined direction D is substantially overlapped with an entirety of the sensing region 211, but the present disclosure is not limited thereto. For example, in other embodiments of the present disclosure not shown in the drawings, the size of the transparent segment 51 can be slightly greater than that of the sensing region 211.

Moreover, the ring-shaped segment 52 has a ring-shaped roughened region 521, and a top side of the supporting layer 4 is substantially gaplessly connected to the ring-shaped roughened region 521. In other words, the top side of the supporting layer 4 and the ring-shaped roughened region 521 are concave-convex structures being complementary to each other. Furthermore, a projection space defined by orthogonally projecting the ring-shaped roughened region 521 toward the top surface 21 of the sensor chip 2 (along the predetermined direction D) is located outside of the sensing region 211 and overlaps an entirety of the supporting layer 4 and a part of the enclosed space E.

Accordingly, the chip-scale sensor package structure 100a of the present embodiment is provided with the ring-shaped roughened region 521 formed on the ring-shaped segment 52 of the light-permeable layer 5, so that the bonding force between the light-permeable layer 5 and the supporting layer 4 can be increased for effectively preventing the light-permeable layer 5 from peeling off the supporting layer 4 or preventing the light-permeable layer 5 and the supporting layer 4 from having a delamination therebetween. It should be noted that the ring-shaped roughened region 521 formed on the light-permeable layer 5 has a lower production difficulty and a lower cost with respect to the ring-shaped roughened region 521 formed on other components (e.g., the sensor chip 2 or the supporting layer 4), so that any roughened region not formed on a light-permeable layer is different from the ring-shaped roughened region 521 provided by the present embodiment.

Moreover, since the chip-scale sensor package structure 100a of the present embodiment is provided with the ring-shaped roughened region 521 formed on the ring-shaped segment 52 of the light-permeable layer 5, light traveling on the ring-shaped roughened region 521 by passing through the light-permeable layer 5 can be scattered to prevent the light from being reflected to the sensing region 211 through the supporting layer 4, thereby effectively reducing the flare phenomenon of the chip-scale sensor package structure 100a.

In addition, the light-permeable layer 5 of the present embodiment is configured to allow that light traveling on the ring-shaped roughened region 521 by passing through the ring-shaped segment 52 is scattered toward the supporting layer 4. In order to enable the supporting layer 4 to be uniformly irradiated, the light-permeable layer 5 of the present embodiment preferably has at least part of the following features, but the present disclosure is not limited thereto.

Specifically, the light-permeable layer 5 has an outer surface 53, an inner surface 54 that is opposite to the outer surface 53, and a surrounding lateral surface 55 that is connected to the outer surface 53 and the inner surface 54. The surrounding lateral surface 55 is preferably flush with or coplanar with an outer side of the supporting layer 4 and an outer side of the sensor chip 2.

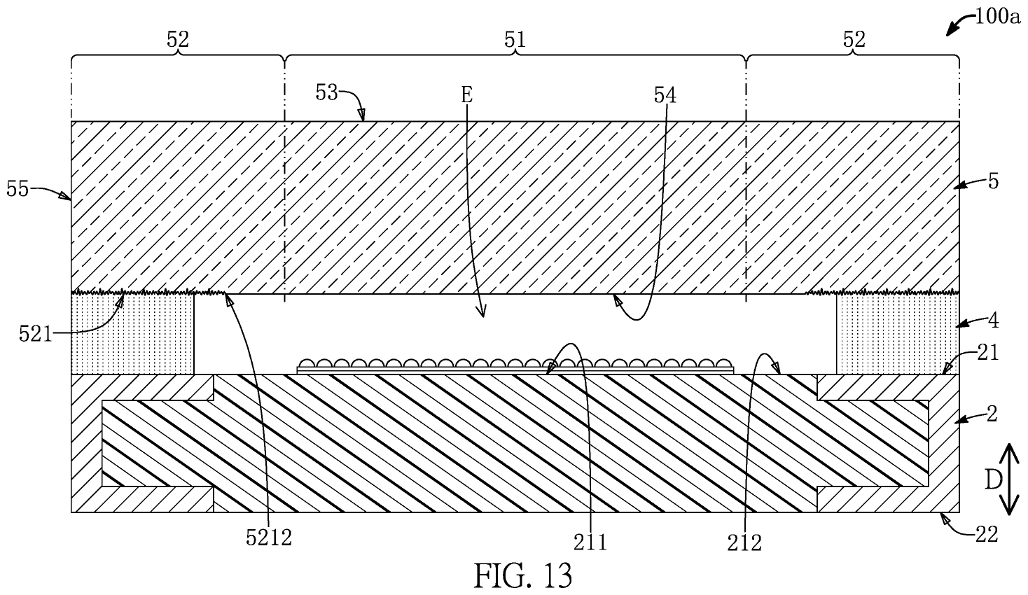

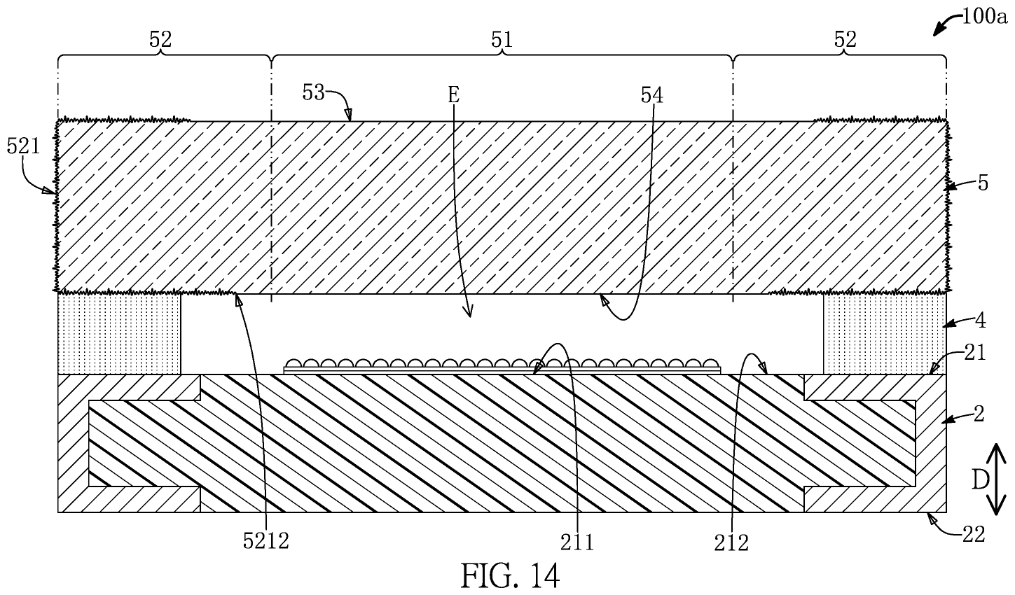

The ring-shaped roughened region 521 is formed on the inner surface 54 of the light-permeable layer 5 (i.e., a part of the inner surface 54 on the ring-shaped segment 52) as shown in FIG. 13 according to design requirements, and an inner edge 5212 of the ring-shaped roughened region 521 is arranged in the enclosed space E (or is arranged inside of the supporting layer 4), but the inner edge 5212 is not in contact with the transparent segment 51. Or, the ring-shaped roughened region 521 can be arranged across an entirety of surface of the ring-shaped segment 52 as shown in FIG. 14 (i.e., the ring-shaped roughened region 521 is arranged on an entirety of the surrounding lateral surface 55, a part of the inner surface 54 arranged on the ring-shaped segment 51, and a part of the outer surface 53 that is arranged on the ring-shaped segment 51).

In addition, the ring-shaped roughened region 521 in the present embodiment has a haze being within a range from 10% to 90%, and the haze is preferably within a range from 30% to 90%, but the present disclosure is not limited thereto.

In summary, when the supporting layer 4 of the chip-scale sensor package structure 100a in the present embodiment is the light curing layer, the ring-shaped roughened region 521 enables a lot of light to be scattered onto the supporting layer 4 by having specific characteristics, so that the supporting layer 4 can be entirely solidified to prevent the light-permeable layer 5 from being tilted and to further prevent the supporting layer 4 and the light-permeable layer from having the delamination therebetween. Accordingly, the yield of the sensor package structure 100 can be increased.

### Sixth Embodiment

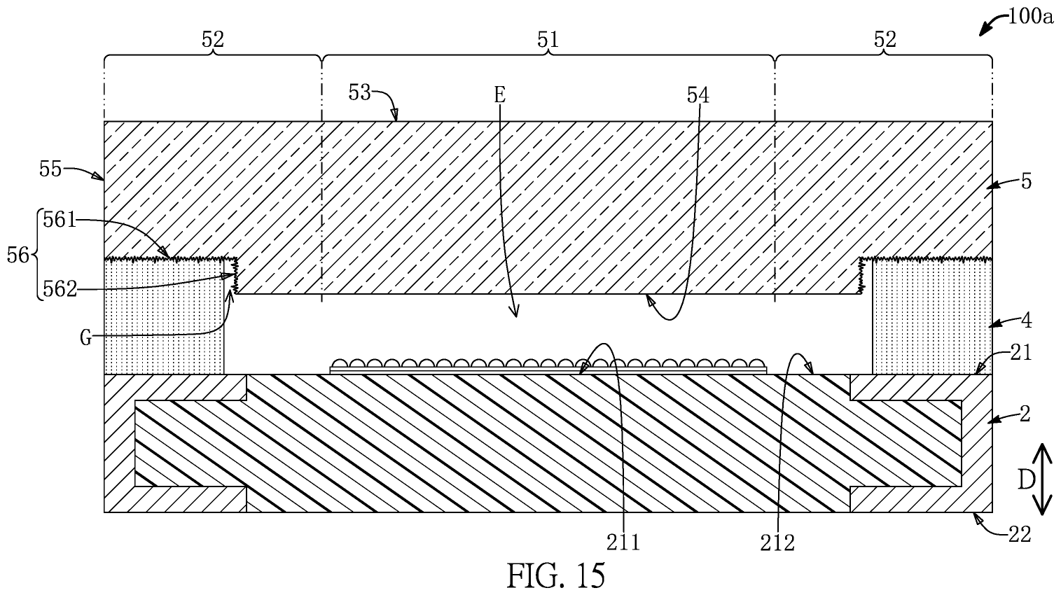

Referring to FIG. 15, a sixth embodiment of the present disclosure, which is similar to the fifth embodiment of the present disclosure, is provided. For the sake of brevity, descriptions of the same components in the fifth and sixth embodiments of the present disclosure will be omitted herein, and the following description only discloses different features between the fifth and sixth embodiments.

In the present embodiment, the ring-shaped segment 52 has an inner ring-shaped groove 56 formed on the inner surface 54. The inner ring-shaped groove 56 has a tread surface 561 (connected to the surrounding lateral surface and a riser surface 562 that connects the tread surface 561 and the inner surface 54. The ring-shaped roughened region 521 is formed on the tread surface 561 and the riser surface 562. The ring-shaped roughened region 521 in the present embodiment is preferably formed on an entirety of the tread surface 561 and an entirety of the riser surface 562, but the present disclosure is not limited thereto.

Specifically, the supporting layer 4 is connected to the tread surface 561 (and a part of the ring-shaped roughened surface 521 arranged on the tread surface 561), and the supporting layer 4 and the riser surface 562 have an overflow gap G therebetween, thereby preventing the supporting layer 4 from extending (or flowing) to the transparent segment 51.

### Seventh Embodiment

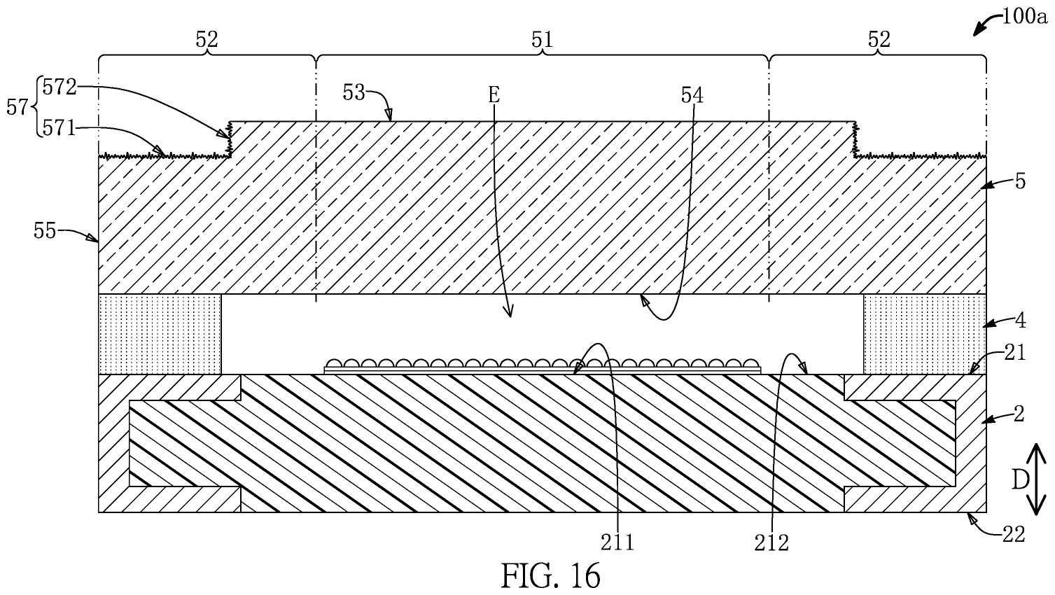

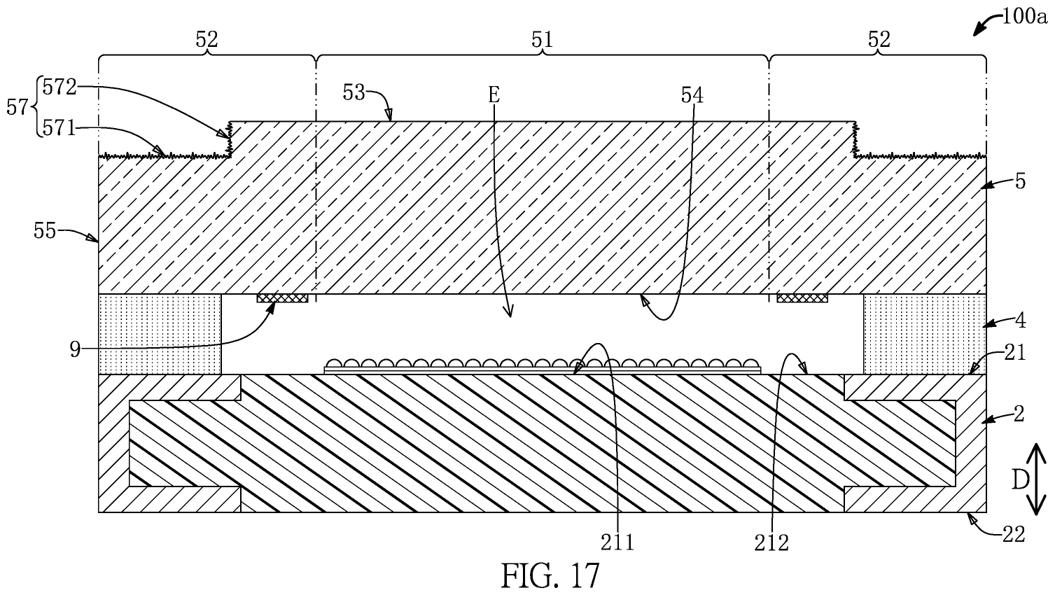

Referring to FIG. 16 and FIG. 17, a seventh embodiment of the present disclosure, which is similar to the first embodiment of the present disclosure, is provided. For the sake of brevity, descriptions of the same components in the fifth and seventh embodiments of the present disclosure will be omitted herein, and the following description only discloses different features between the fifth and seventh embodiments.

In the present embodiment, the ring-shaped segment 52 has an outer ring-shaped groove 57 formed on the outer surface 53. The outer ring-shaped groove 57 has a tread surface 571 (connected to the surrounding lateral surface and a riser surface 572 that connects the tread surface 571 and the outer surface 53. The ring-shaped roughened region 521 is formed on the tread surface 571 and the riser surface 572. The ring-shaped roughened region 521 in the present embodiment is preferably formed on an entirety of the tread surface 571 and an entirety of the riser surface 572, but the present disclosure is not limited thereto.

In addition, as shown in FIG. 17, the chip-scale sensor package structure 100 of the present embodiment further includes a shielding ring 9 formed on the inner surface 54, and the shielding ring 9 is preferably arranged on the ring-shaped segment 52. In other words, a projection region defined by orthogonally projecting the shielding ring 9 onto the top surface 21 of the sensor chip 2 is located between the sensing region 211 and the supporting layer 4. Moreover, the riser 572 and a part of the ring-shaped roughened region arranged thereon in the present embodiment are located direct above the shielding ring 9.

Accordingly, the chip-scale sensor package structure 100a in the present embodiment is provided with the shielding ring 9 located at a specific position, thereby effectively reducing an interference of the sensing region 211 resulted by light and further reducing the flare phenomenon of the chip-scale sensor package structure 100a.

### Beneficial Effects of the Embodiments

In conclusion, any one of the sensor package structure and the chip-scale sensor package structure in the present disclosure is provided with the ring-shaped roughened region formed on the ring-shaped segment of the light-permeable layer, so that the bonding force between the light-permeable layer and the supporting layer can be increased for effectively preventing the light-permeable layer from peeling off the supporting layer or preventing the light-permeable layer and the supporting layer from having a delamination therebetween.

Moreover, since any one of the sensor package structure and the chip-scale sensor package structure in the present disclosure is provided with the ring-shaped roughened region formed on the ring-shaped segment of the light-permeable layer, light arrived at the ring-shaped roughened region by passing through the light-permeable layer can be scattered to prevent the light from being reflected to the sensing region through the supporting layer, thereby effectively reducing the flare phenomenon of any one of the sensor package structure and the chip-scale sensor package structure.

In addition, when the supporting layer of any one of the sensor package structure and the chip-scale sensor package structure in the present disclosure is the light curing layer, the ring-shaped roughened region enables a lot of light to be scattered onto the supporting layer by having specific characteristics, so that the supporting layer can be entirely solidified to prevent the light-permeable layer from being tilted and to further prevent the supporting layer and the light-permeable layer from having the delamination therebetween. Accordingly, the yield of any one of the sensor package structure and the chip-scale sensor package structure can be increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
a sensor chip disposed on and electrically coupled to the substrate, wherein a top surface of the sensor chip includes a sensing region and a carrying region that surrounds the sensing region;
a supporting layer having a ring shape and being disposed on the carrying region of the sensor chip;
a light-permeable layer having an outer surface and an inner surface that is opposite to the outer surface, wherein the light-permeable layer has a transparent segment and a ring-shaped segment that surrounds the transparent segment, and wherein the ring-shaped segment is disposed on the supporting layer, so that the light-permeable layer, the supporting layer, and the sensor chip jointly define an enclosed space; and
an encapsulant formed on the substrate, wherein the sensor chip, the supporting layer, and the light-permeable layer are embedded in the encapsulant, and at least part of the outer surface of the light-permeable layer is exposed from the encapsulant;
wherein the ring-shaped segment has a ring-shaped roughened region, and a projection space defined by orthogonally projecting the ring-shaped roughened region toward the top surface of the sensor chip is located outside of the sensing region and overlaps an entirety of the supporting layer and a part of the enclosed space.

2. The sensor package structure according to claim 1, wherein the ring-shaped roughened region has a haze being within a range from 10% to 90%.

3. The sensor package structure according to claim 1, wherein the ring-shaped roughened region is a patterned array.

4. The sensor package structure according to claim 1, wherein the ring-shaped roughened region is formed on the inner surface of the light-permeable layer, an outer edge of the ring-shaped roughened region is arranged outside of the supporting layer, and an inner edge of the ring-shaped roughened region is flush with an inner side of the supporting layer.

5. The sensor package structure according to claim 4, further comprising an anti-reflection layer formed on the inner surface of the light-permeable layer, wherein the anti-reflection layer covers the ring-shaped roughened region.

6. The sensor package structure according to claim 4, further comprising an anti-reflection layer formed on the inner surface of the light-permeable layer, wherein the anti-reflection layer is arranged inside of the ring-shaped roughened region.

7. The sensor package structure according to claim 1, wherein the ring-shaped segment has an inner ring-shaped groove formed on the inner surface of the light-permeable layer, wherein the inner ring-shaped groove has a tread surface and a riser surface that connects the tread surface and the inner surface, and wherein the ring-shaped roughened region is formed on the tread surface and the riser surface, and the supporting layer is connected to the tread surface.

8. The sensor package structure according to claim 7, wherein the encapsulant covers a part of the tread surface, and the supporting layer and the riser surface have an overflow gap therebetween.

9. The sensor package structure according to claim 1, wherein the ring-shaped segment has an outer ring-shaped groove formed on the outer surface, wherein the outer ring-shaped groove has a tread surface and a riser surface that connects the tread surface and the outer surface, and wherein the ring-shaped roughened region is formed on the tread surface and the riser surface, and a top side of the encapsulant is flush with the tread surface.

10. The sensor package structure according to claim 1, further comprising a plurality of metal wires, wherein two ends of each of the metal wires are respectively connected to the substrate and the carrying region of the sensor chip, so that the substrate and the sensor chip are electrically coupled to each other, and wherein each of the metal wires is located outside of the supporting layer and is embedded in the encapsulant.

11. The sensor package structure according to claim 1, further comprising a plurality of metal wires, wherein two ends of each of the metal wires are respectively connected to the substrate and the carrying region of the sensor chip, so that the substrate and the sensor chip are electrically coupled to each other, and wherein a part of each of the metal wires is embedded in the supporting layer, and a remaining part of each of the metal wires is embedded in the encapsulant.

12. The sensor package structure according to claim 1, wherein the supporting layer is an ultraviolet (UV) curing layer, and the light-permeable layer is configured to allow light passing through the ring-shaped segment to be scattered at the ring-shaped roughened region toward the supporting layer.

13. A chip-scale sensor package structure, comprising:
a sensor chip, wherein a top surface of the sensor chip includes a sensing region and a carrying region that surrounds the sensing region;
a supporting layer having a ring shape and being disposed on the carrying region of the sensor chip; and
a light-permeable layer having an outer surface and an inner surface that is opposite to the outer surface, wherein the light-permeable layer has a transparent segment and a ring-shaped segment that surrounds the transparent segment, and wherein the ring-shaped segment is disposed on the supporting layer, so that the light-permeable layer, the supporting layer, and the sensor chip jointly define an enclosed space;
wherein the ring-shaped segment has a ring-shaped roughened region, and a projection space defined by orthogonally projecting the ring-shaped roughened region toward the top surface of the sensor chip is located outside of the sensing region and overlaps an entirety of the supporting layer and a part of the enclosed space.

14. The chip-scale sensor package structure according to claim 13, wherein the ring-shaped roughened region has a haze being within a range from 10% to 90%.

15. The chip-scale sensor package structure according to claim 13, wherein the ring-shaped roughened region is formed on the inner surface of the light-permeable layer, and an inner edge of the ring-shaped roughened region is located in the enclosed space.

16. The chip-scale sensor package structure according to claim 13, wherein the ring-shaped segment has an inner ring-shaped groove formed on the inner surface, wherein the inner ring-shaped groove has a tread surface and a riser surface that connects the tread surface and the inner surface, and wherein the ring-shaped roughened region is formed on the tread surface and the riser surface, and the supporting layer is connected to the tread surface.

17. The chip-scale sensor package structure according to claim 16, wherein the supporting layer and the riser surface have an overflow gap therebetween.

18. The chip-scale sensor package structure according to claim 13, wherein the ring-shaped segment has an outer ring-shaped groove formed on the outer surface, wherein the outer ring-shaped groove has a tread surface and a riser surface that connects the tread surface and the outer surface, and wherein the ring-shaped roughened region is formed on the tread surface and the riser surface, and a top side of the encapsulant is flush with the tread surface.

19. The chip-scale sensor package structure according to claim 1, further comprising a shielding ring formed on the inner surface, and a projection region defined by orthogonally projecting the shielding ring onto the top surface of the sensor chip is located between the sensing region and the supporting layer.

20. The chip-scale sensor package structure according to claim 13, wherein the ring-shaped roughened region is arranged across an entirety of surface of the ring-shaped segment.
